(19) United States
(12) Patent Application Publication
(10) Pub. No.: US 2023/0051200 A1
(43) Pub. Date: Feb. 16, 2023

(54) SEAM-FREE GAPFILL DEPOSITION

(71) Applicant: Applied Materials, Inc., Santa Clara, CA (US)

(72) Inventors: Qinghua Zhao, Sunnyvale, CA (US); Rui Cheng, San Jose, CA (US); Karthik Janakiraman, San Jose, CA (US)

(73) Assignee: Applied Materials, Inc., Santa Clara, CA (US)

(21) Appl. No.: 17/399,702

(22) Filed: Aug. 11, 2021

(51) Int. Cl. H01L 21/02; H01L 21/762

(52) U.S. Cl. CPC H01L 21/02167; H01L 21/76224; H01L 21/02208; H01L 21/02274

(57) ABSTRACT

Exemplary methods of semiconductor processing may include providing a silicon-containing precursor to a processing region of a semiconductor processing chamber. The methods may include depositing a silicon-containing layer on surfaces defining the processing region of the semiconductor processing chamber. The methods may include forming a plasma of a hydrogen-containing precursor within the processing region of the semiconductor processing chamber. The methods may include depositing a silicon-containing material on a substrate disposed within the processing region of the semiconductor processing chamber.

### TECHNICAL FIELD

The present technology relates to methods and components for semiconductor processing. More specifically, the present technology relates to systems and methods for producing silicon-containing films for semiconductor structures.

### BACKGROUND

Integrated circuits are made possible by processes which produce intricately patterned material layers on substrate surfaces. Producing patterned material on a substrate requires controlled methods for forming and removing material. As device sizes continue to reduce, aspect ratios of structures may grow, and maintaining dimensions of these structures during processing operations may be challenged. Developing materials that may have sufficient fill characteristics across features may become more difficult. Additionally, as the number of material layers being patterned during processing is expanding, producing materials that may have improved removal selectivity to other exposed materials is becoming a greater challenge, along with maintaining material properties.

Thus, there is a need for improved systems and methods that can be used to produce high quality devices and structures. These and other needs are addressed by the present technology.

### SUMMARY

Exemplary methods of semiconductor processing may include providing a silicon-containing precursor to a processing region of a semiconductor processing chamber. The methods may include depositing a silicon-containing layer on surfaces defining the processing region of the semiconductor processing chamber. The methods may include forming a plasma of a hydrogen-containing precursor within the processing region of the semiconductor processing chamber. The methods may include depositing a silicon-containing material on a substrate disposed within the processing region of the semiconductor processing chamber.

In some embodiments, the methods may include, subsequent depositing the silicon-containing layer, delivering the substrate into the processing region of the semiconductor processing chamber. The processing region of the semiconductor processing chamber may be defined by a faceplate, and the silicon-containing layer may be formed on a surface of the faceplate facing the processing region of the semiconductor processing chamber. The methods may include increasing a pressure within the processing region of the semiconductor processing chamber while forming the plasma of the hydrogen-containing precursor. The processing region of the semiconductor processing chamber may be defined between a faceplate and a substrate support. The faceplate may be maintained at a first temperature, and the substrate support may be maintained at a second temperature greater than the first temperature. The silicon-containing layer may include nitrogen, carbon, and/or a dopant. The hydrogen-containing precursor may be or include diatomic hydrogen. The methods may include halting delivery of the silicon-containing precursor prior to forming the plasma of the hydrogen-containing precursor. The silicon-containing layer may be deposited by plasma-enhanced deposition performed at a first plasma power. Forming the plasma of the hydrogen-containing precursor may be performed at a second plasma power greater than the first plasma power.

Some embodiments of the present technology may encompass semiconductor processing methods. The methods may include providing a silicon-containing precursor to a processing region of a semiconductor processing chamber. The methods may include forming a plasma of the silicon-containing precursor within the processing region of the semiconductor processing chamber. The methods may include depositing a silicon-containing layer within the processing region of the semiconductor processing chamber. The methods may include halting delivery of the silicon-containing precursor. The methods may include forming a plasma of a hydrogen-containing precursor within the processing region of the semiconductor processing chamber. The methods may include depositing a silicon-containing material on a substrate disposed within the processing region of the semiconductor processing chamber.

In some embodiments, the methods may include, subsequent depositing the silicon-containing layer, delivering the substrate into the processing region of the semiconductor processing chamber. The methods may include increasing a pressure within the processing region of the semiconductor processing chamber while forming the plasma of the hydrogen-containing precursor. The silicon-containing layer may include nitrogen, carbon, and/or a dopant, and the hydrogen-containing precursor may be or include diatomic hydrogen. Forming the plasma of the silicon-containing precursor may be performed at a first plasma power, and forming the plasma of the hydrogen-containing precursor may be performed at a second plasma power greater than the first plasma power. The semiconductor processing method may be performed at a substrate temperature of greater than or about 200° C.

Some embodiments of the present technology may encompass semiconductor processing methods. The methods may include providing a silicon-containing precursor to a processing region of a semiconductor processing chamber. The methods may include depositing a silicon-containing layer within the processing region of the semiconductor processing chamber. The methods may include, subsequent depositing the silicon-containing layer, providing a substrate to the processing region of the semiconductor processing chamber. The methods may include forming a plasma of a hydrogen-containing precursor within the processing region of the semiconductor processing chamber. The methods may include depositing a silicon-containing material on the substrate disposed within the processing region of the semiconductor processing chamber.

In some embodiments, the silicon-containing layer may include nitrogen, carbon, and/or a dopant, and the hydrogen-containing precursor may include diatomic hydrogen. The silicon-containing layer may be deposited by plasma-enhanced deposition performed at a first plasma power, and forming the plasma of the hydrogen-containing precursor may be performed at a second plasma power greater than the first plasma power. The processing region of the semiconductor processing chamber may be defined between a faceplate and a substrate support. The silicon-containing layer may be deposited on the faceplate. The faceplate may be maintained at a first temperature, and the substrate support may be maintained at a second temperature greater than the first temperature.

Such technology may provide numerous benefits over conventional systems and techniques. For example, embodiments of the present technology may produce bottom-up deposition, which may be applicable to a number of substrate features. Additionally, the present technology may produce silicon-containing films for plug and gapfill applications, as well as any other application for which reduced seam or void formation may be a benefit. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary plasma system according to some embodiments of the present technology.

FIG. 2 shows operations in a semiconductor processing method according to some embodiments of the present technology.

FIGS. 3A-3C show schematic views of an exemplary processing system while performing processes according to some embodiments of the present technology.

FIG. 4 shows an exemplary schematic cross-sectional structure in which material is deposited according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As device sizes continue to shrink, many material layers may be reduced in thickness and size to scale devices. Aspect ratios may also increase, and more improved material formation may be desired. These materials may be used in gapfill and other deposition operations to separate and/or protect other materials. Additionally, as the number of materials on a surface to be processed may increase, a greater number of materials may be utilized to increase selectivity during subsequent removal or processing. As one non-limiting example, a number of silicon-containing materials may be utilized in a growing number of high-aspect ratio applications.

Conventional technologies have struggled to produce gapfill materials that may adequately accommodate device structures, especially structures having deeper recesses or features. Blanket deposition of silicon-containing materials, for example, may cause air gaps and voids to develop in devices being produced due to over deposition at the surface and under deposition within the features, which may include trenches, plugs, or other structures that may be characterized by increased aspect ratios. Additionally, conformal formation by chemical-vapor deposition may be challenged for higher aspect ratio structures. For example, conformal formation may produce seams or voids extending through the fill, which may be exposed in subsequent processing, causing oxidation or other damage within the structure.

The present technology overcomes these issues by performing a directional deposition of silicon-containing materials. By first coating chamber surfaces with silicon-containing materials, a subsequent plasma formation may be used to drive deposition materials from the chamber surfaces, and which may preferentially fill substrate features in a bottom-up deposition. This may afford seam-free gapfill and other deposition, which may accommodate any number of semiconductor structures. Although the remaining disclosure will routinely identify specific deposition processes utilizing the disclosed technology, and will describe one type of semiconductor processing chamber, it will be readily understood that the processes described may be performed in any number of semiconductor processing chambers. Accordingly, the technology should not be considered to be so limited as for use with these specific deposition processes or chambers alone. The disclosure will discuss one possible chamber that may be used to perform processes according to embodiments of the present technology before methods of semiconductor processing according to the present technology are described.

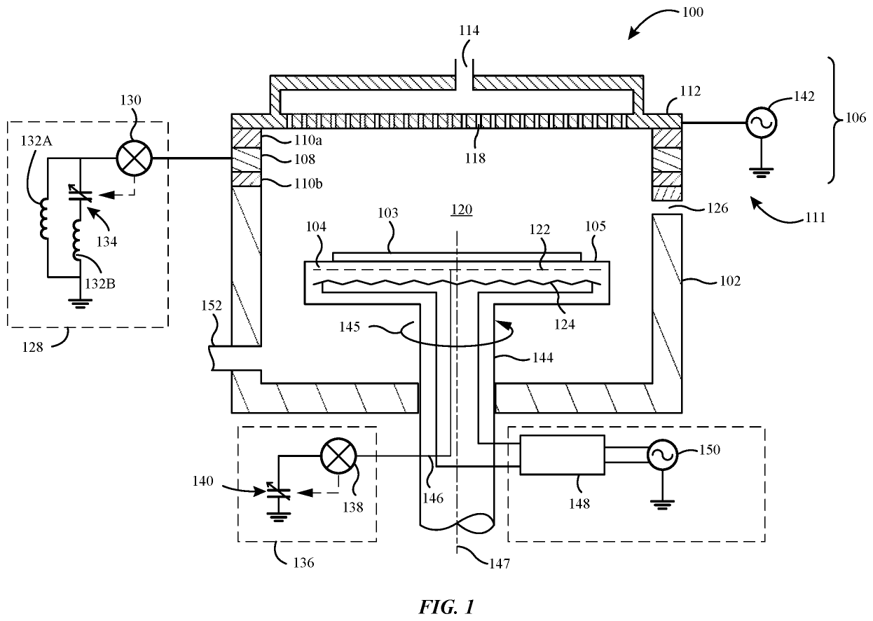

FIG. 1 shows a cross-sectional view of an exemplary processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers according to some embodiments of the present technology, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition process.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power. The substrate support 104 may also include one or more heating elements configured to heat the substrate to a processing temperature, which may be between about 25° C. and about 800° C. or greater.

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

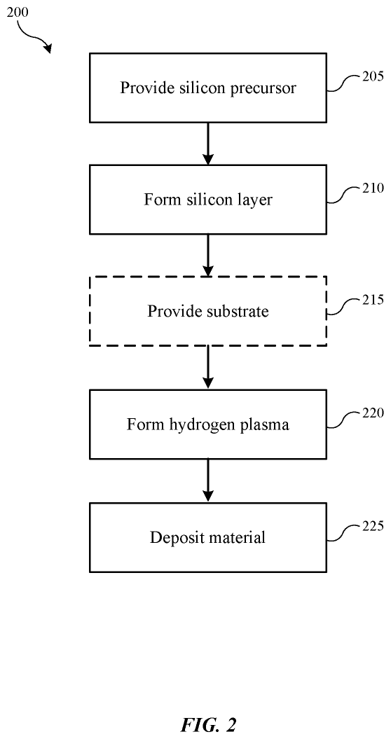

As discussed previously, the present technology may first coat surfaces of a semiconductor processing chamber with materials that may subsequently be deposited on the substrate. Accordingly, any number of substrate processing chambers may be used, and the chamber may be configured in any number of ways to facilitate the deposition processes. FIG. 2 shows exemplary operations in a processing method 200 according to some embodiments of the present technology. The method may be performed in a variety of processing chambers, including processing chamber 100 described above, as well as any other chambers in which a local plasma may be formable, and in which one or more operations may be performed.

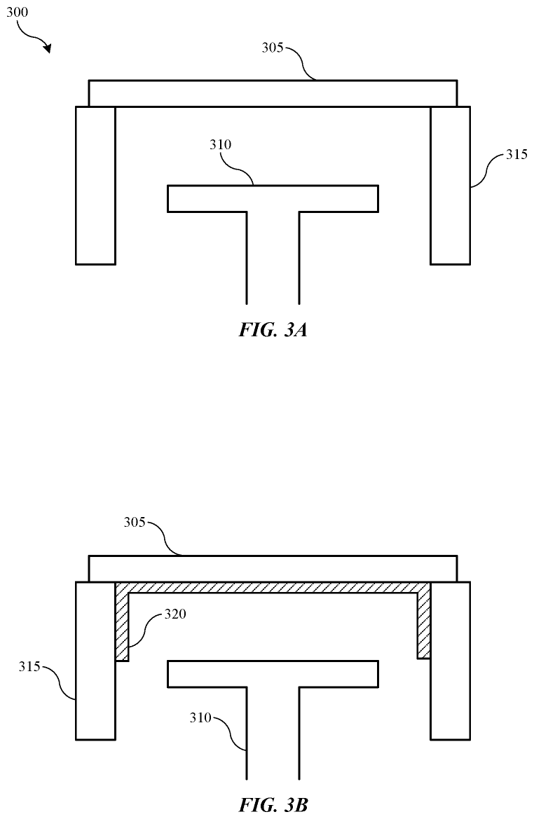

Method 200 may include one or more operations prior to the initiation of the method, including front-end processing, deposition, etching, polishing, cleaning, or any other operations that may be performed prior to the described operations. The methods may include a number of optional operations, which may or may not be specifically associated with some embodiments of methods according to embodiments of the present technology. For example, many of the operations are described in order to provide a broader scope of the processes performed, but are not critical to the technology, or may be performed by alternative methodology as will be discussed further below. Method 200 may describe operations shown schematically in FIGS. 3A-3C, the illustrations of which will be described in conjunction with the operations of method 200. It is to be understood that the figures illustrate only partial schematic views, and a chamber may contain any number of additional components or features as would be readily appreciated by the skilled artisan.

Method 200 may or may not involve optional operations to develop the semiconductor structure to a particular fabrication operation. It is to be understood that method 200 may be performed on any number of semiconductor structures or substrates, as will be described further below. However, in some embodiments, one or more operations of method 200 may be performed prior to delivery of the substrate into the semiconductor processing chamber. As explained above, chemical-vapor deposition often produces conformal films, which may produce seams in trenches and other structures, despite being capable of accessing high-aspect ratio features. The present technology may first form a layer of material on surfaces of the semiconductor processing chamber, which may facilitate deposition on a substrate in subsequent operations that produce directional deposition, and which may provide seam-free filling.

For example, at operation 205, a silicon-containing precursor may be delivered to a processing region of a semiconductor processing chamber. As illustrated in FIG. 3A, a processing chamber 300 may include any number of components, and the processing region may be defined by one or more components of the semiconductor processing chamber. It is to be understood that FIG. 3A illustrates only a schematic representation of a processing region, which may include any aspect of chamber 100 discussed above. For example, exemplary chambers may include a faceplate 305 and a substrate support 310, which may define a processing region between them, and may be configured to generate a plasma within the region as discussed above, such as a capacitively-coupled plasma. Additionally, the processing region may be defined radially or laterally by one or more components 315. For example, components 315 may be or include isolators, liners, or any other component that may be incorporated in a semiconductor processing chamber.

The silicon-containing precursor may be any number of precursors as discussed further below, and the silicon-containing precursor may be delivered into the processing region with any number of additional precursors to produce a number of films. At operation 210, a layer of silicon-containing material may be deposited on surfaces of the processing region. The deposition may occur in a number of ways, and may include both thermal deposition, where the precursors may thermally decompose and deposit on surfaces, as well as a plasma-enhanced deposition. In some embodiments, the silicon-containing precursor may be delivered to the processing region, and a plasma may be generated in the processing region to produce silicon-containing radical species. The species may contact surfaces of the processing region and deposit a silicon-containing material. For example, as illustrated in FIG. 3B, after a plasma is generated from the silicon-containing precursor, a silicon-containing layer 320 may be formed or deposited on exposed surfaces in the semiconductor processing chamber, which may define the processing region. As illustrated, the silicon-containing layer may be defined along the surface of faceplate 305 that faces the processing region, as well as the interior surfaces of components 315.

In some embodiments the silicon-containing layer may also be formed or deposited on the substrate support 310, although the formation may or may not be equivalent to the deposition on other exposed surfaces within the region. For example, in some embodiments the faceplate may be heated to a first temperature, such as with a heater extending about and contacting the faceplate, or incorporated in one or more additional components in which the faceplate is in thermal communication. Additionally, the substrate support may be heated to a second temperature different from the first, and which may be greater than the first in some embodiments of the present technology. Depending on the silicon-containing material being deposited, by maintaining the substrate support at a higher temperature, the silicon-containing materials may be less likely to condense or form across the component. Similarly, by maintaining a lower temperature of the faceplate and sidewall components, increased deposition may occur on those exposed surfaces. Additionally, in some embodiments the silicon may already be incorporated on the faceplate, such as in a coating previously applied. The coating may be a sufficient thickness to operate as the source of the silicon-containing material discussed throughout the present technology. In these situations, the operations of providing the silicon precursor and forming the layer may not be performed, and the method may begin with the hydrogen treatment discussed below.

The temperature of any of the components may be maintained at greater than or about 100° C., and may be maintained at greater than or about 150° C., greater than or about 200° C., greater than or about 250° C., greater than or about 300° C., greater than or about 350° C., greater than or about 400° C., greater than or about 450° C., greater than or about 500° C., greater than or about 550° C., greater than or about 600° C., or greater. Additionally, in some embodiments, while the substrate support may be maintained at greater than or about 200° C., the faceplate may be maintained at less than or about 200° C., which may facilitate deposition along the faceplate. Subsequent to the deposition on the surfaces, in some embodiments, delivery of the silicon-containing precursor may be halted, along with delivery of any other precursors, such as dopants, carrier gases, or any other deposition materials.

At optional operation 215, after formation of the layer of silicon-containing material, a substrate may be delivered to the processing region, such as by delivering the substrate to the processing chamber, and/or placing the substrate on the substrate support. The substrate may include any feature or characteristic, including one or more high-aspect ratio features in embodiments of the present technology. As shown in FIG. 3C, substrate 325 may be positioned on the substrate support 310 in the processing chamber in which the silicon-containing layer 320 was previously deposited. Substrate 325 may be or include any number of materials, such as a base wafer or substrate made of silicon or silicon-containing materials, germanium, other substrate materials, as well as one or more materials that may be formed overlying the substrate during semiconductor processing. For example, in some embodiments the substrate may be processed to include one or more materials or structures for semiconductor processing, such as dielectric materials, metal materials, or any other substrate material. Substrate 325 may define any number of features or recesses along the substrate, including one or more high-aspect ratio features.

For example, the aspect ratio of any of the features, or the ratio of the depth of the feature relative to the width or diameter of the feature formed, may be greater than or about 2:1, and may be greater than or about 3:1, greater than or about 4:1, greater than or about 5:1, greater than or about 6:1, greater than or about 7:1, greater than or about 8:1, greater than or about 9:1, greater than or about 10:1, or more. Because of the depth of these features, a plasma-deposited layer may be incapable of sufficiently accessing deeper within the trench, and pinch-off may occur at the top of the feature. Similarly, conformal deposition may produce a seam or void that may similarly pinch off the formation, or may maintain access into the structure through the seam. However, silicon-containing films produced by the present technology may be characterized by coverage through the structure that may be produced in a bottom-up fill, which may maintain the access to the feature during deposition as will be described further below.

With a substrate in the processing chamber and the layer of silicon-containing material on the processing region surfaces, a hydrogen-containing precursor may be delivered to the substrate processing region of the semiconductor processing chamber. At operation 220, a plasma may be formed of the hydrogen-containing precursor within the semiconductor processing region. Hydrogen plasma effluents may interact with the silicon-containing material, and may reverse at least some of the silicon-containing material to a gas-phase material. This material may then flow to the substrate, and a silicon-containing material may deposit on the substrate at operation 225. The material deposited may preferentially deposit within the features formed on the substrate, which may provide a bottom-up fill within the features.

In some embodiments, during the material deposition on the substrate, no additional silicon-containing material may be delivered into the processing chamber, and the material deposited on the surfaces of the processing region may provide the silicon material for the deposition. Although one or more inert or carrier gases may be provided with the hydrogen-containing material in some embodiments, no other precursor may be provided with the hydrogen-containing precursor. Without being bound to any particular theory, the hydrogen plasma may reverse a portion of the silicon-containing material to a gas-phase species, which may be plasma enhanced. However, although a hydrogenated silicon material characterized by one or more silicon-hydrogen bonds, the produced material may not be fully converted to the initial silicon-containing precursor used during the silicon deposition. Accordingly, the produced material may more readily deposit on surfaces of the substrate. Additionally, because of the hydrogen plasma generation, the hydrogen may be used to at least partially etch materials from depositing on the upper surfaces of the substrate.

Hydrogen plasma effluents may not as readily extend through high-aspect ratio features, which may allow more material to deposit from the bottom upwards in the feature without being etched. However, the hydrogen plasma effluents may fully remove deposition products from exposed upper surfaces of the substrate, and within the mouth of the features. By performing embodiments of the present technology utilizing parameters discussed throughout this disclosure, the hydrogen effluents may have sufficient energy for removal at the entrance to the feature, while losing energy within the feature, and being unable to energetically remove materials deposited within the structure. These competing processes may allow deposition to continue up through the feature, while limiting or preventing deposition that can cause a seam or void to form by pinching off the mouth of the feature. For conventional deposition in which the silicon-containing precursor is delivered simultaneously, the deposition process may overcome the etch aspects when plasma is formed of both materials together, and a bottom-up and/or seamless fill may not occur. However, by first depositing the silicon-containing material on chamber surfaces, and subsequently forming a hydrogen plasma that may interact with the deposited silicon material, deposition may be performed that produces a bottom-up fill.

Any number of precursors may be used in embodiments of the present technology, and a number of silicon-containing materials may be formed by embodiments of the present technology. Non-limiting examples of silicon-containing precursors that may be used during processing according to some embodiments of the present technology may include silane, disilane, silicon tetrafluoride, silicon tetrachloride, dichlorosilane, organosilanes, as well as any other silicon-containing precursors that may be used in silicon-containing film formation. During formation of the silicon-containing layer, one or more additional precursors may be delivered in some embodiments, which may produce additional silicon-containing materials. For example, a nitrogen-containing precursor and/or a carbon-containing precursor may be delivered with the silicon-containing precursor to produce a silicon nitride, silicon carbide, or silicon carbonitride material. Additionally, one or more dopant materials may be provided, such as boron as one non-limiting example, and which may produce a doped silicon film. The hydrogen-containing plasma may be formed from diatomic hydrogen in some embodiments, although any number of other hydrogen-containing materials may be used. For example, when nitrogen or carbon-containing silicon materials are formed, the hydrogen-containing material may include nitrogen or carbon, respectively, which may help maintain atomic ratios of the deposited materials. Additional materials that may be flowed with the precursors during the deposition may be or include nitrogen, argon, helium, or any number of other carrier gases.

Other chamber conditions may be adjusted during the deposition operations between the silicon deposition on the chamber surfaces, and silicon deposition on the substrate. For example, during the silicon-containing layer deposition on the chamber surfaces, a relatively lower pressure may be maintained in the processing region to control plasma effluent energy. However, for the hydrogen plasma treatment, the pressure may be increased in some embodiments while forming the hydrogen plasma. Increasing the pressure during the hydrogen treatment may increase hydrogen atoms within the volume, increasing the ability to produce gas phase species of the silicon material to facilitate deposition on the substrate. This may also increase an amount of impact of hydrogen radicals on the upper surfaces of the substrate, which may reduce or limit deposition on these surfaces, while allowing deposition products to flow through the features where plasma effluents may not extend, and which may allow the bottom-up fill. Accordingly, in some embodiments a pressure during the silicon-containing layer deposition on the chamber surfaces may be maintained at less than or about 12 Torr, and may be maintained at less than or about 10 Torr, less than or about 8 Torr, less than or about 6 Torr, less than or about 4 Torr, less than or about 2 Torr, or less. During formation of the hydrogen plasma, or during some or all of operation 220 through operation 225 pressure may be increased to greater than or about 4 Torr, and may be increased to greater than or about 6 Torr, greater than or about 8 Torr, greater than or about 10 Torr, greater than or about 20 Torr, or greater.

Similarly, a plasma power may be adjusted between the two operations. For example, during deposition of the silicon-containing layer on the chamber surfaces, a first plasma power may be used, which may facilitate decomposition of the silicon-containing precursor, while limiting impact on chamber components. For example, in some embodiments plasma power while generating a plasma of the silicon-containing precursor may be less than or about 500 W, and may be less than or about 450 W, less than or about 400 W, less than or about 350 W, less than or about 300 W, less than or about 250 W, less than or about 200 W, less than or about 150 W, less than or about 100 W, or less. However, during formation of the hydrogen-containing plasma, a second plasma power may be used, which may be greater than the first plasma power. This may increase impact with bombardment and energy for both generating silicon-containing species for deposition, and for hydrogen species facilitating removal of silicon or other deposition products along upper surfaces of the substrate features. Accordingly, in some embodiments, the plasma power while generating the plasma of the hydrogen-containing precursor may be greater than or about 200 W, and may be greater than or about 300 W, greater than or about 400 W, greater than or about 500 W, greater than or about 600 W, greater than or about 700 W, greater than or about 800 W, greater than or about 900 W, greater than or about 1000 W, greater than or about 1100 W, greater than or about 1200 W, greater than or about 1300 W, greater than or about 1400 W, greater than or about 1500 W, or higher.

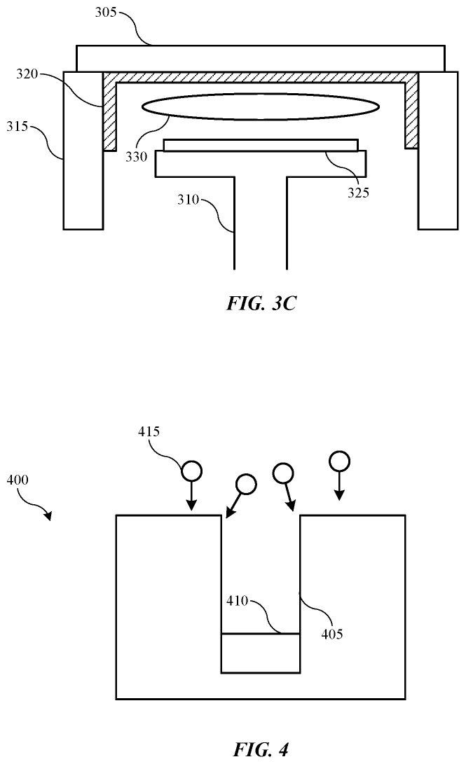

FIG. 4 shows an exemplary schematic cross-sectional structure in which material is deposited according to some embodiments of the present technology. As explained previously, a substrate 400 may be positioned within a processing region of the chamber, and may define one or more features 405, which may be a high-aspect ratio feature as discussed above. The substrate may be or include any number of materials, and may define any number of features, as previously described. In some embodiments, a silicon-containing material may previously have been deposited on exposed surfaces of the processing chamber. A plasma may be generated of a hydrogen precursor, such as diatomic hydrogen, which may produce silicon-containing species that may be deposited directionally within the features to produce a silicon-containing material 410. Additionally, hydrogen radical species 415 may continue to impact the upper or exposed surfaces of the substrate, which may limit or prevent deposition along exterior surfaces and/or along a mouth of the feature. By increasing a time of the hydrogen plasma generation, an increased amount of material may be deposited, allowing the high-aspect ratio structure to be filled. Because the deposition may be bottom-up by nature, due to the competing etch process occurring, the present technology may facilitate a seam-free fill of substrate features.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursor, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a silicon-containing precursor to a processing region of a semiconductor processing chamber;
depositing a silicon-containing layer on surfaces defining the processing region of the semiconductor processing chamber;
forming a plasma of a hydrogen-containing precursor within the processing region of the semiconductor processing chamber; and
depositing a silicon-containing material on a substrate disposed within the processing region of the semiconductor processing chamber.

2. The semiconductor processing method of claim 1, further comprising:
subsequent depositing the silicon-containing layer, delivering the substrate into the processing region of the semiconductor processing chamber.

3. The semiconductor processing method of claim 1, wherein the processing region of the semiconductor processing chamber is defined by a faceplate, and wherein the silicon-containing layer is formed on a surface of the faceplate facing the processing region of the semiconductor processing chamber.

4. The semiconductor processing method of claim 1, further comprising:
increasing a pressure within the processing region of the semiconductor processing chamber while forming the plasma of the hydrogen-containing precursor.

5. The semiconductor processing method of claim 1, wherein the processing region of the semiconductor processing chamber is defined between a faceplate and a substrate support, wherein the faceplate is maintained at a first temperature, and wherein the substrate support is maintained at a second temperature greater than the first temperature.

6. The semiconductor processing method of claim 1, wherein the silicon-containing layer further comprises nitrogen, carbon, and/or a dopant.

7. The semiconductor processing method of claim 1, wherein the hydrogen-containing precursor comprises diatomic hydrogen.

8. The semiconductor processing method of claim 1, further comprising:
halting delivery of the silicon-containing precursor prior to forming the plasma of the hydrogen-containing precursor.

9. The semiconductor processing method of claim 1, wherein the silicon-containing layer is deposited by plasma-enhanced deposition performed at a first plasma power.

10. The semiconductor processing method of claim 9, wherein forming the plasma of the hydrogen-containing precursor is performed at a second plasma power greater than the first plasma power.

11. A semiconductor processing method comprising:
providing a silicon-containing precursor to a processing region of a semiconductor processing chamber;
forming a plasma of the silicon-containing precursor within the processing region of the semiconductor processing chamber;
depositing a silicon-containing layer within the processing region of the semiconductor processing chamber;
halting delivery of the silicon-containing precursor;
forming a plasma of a hydrogen-containing precursor within the processing region of the semiconductor processing chamber; and
depositing a silicon-containing material on a substrate disposed within the processing region of the semiconductor processing chamber.

12. The semiconductor processing method of claim 11, further comprising:
subsequent depositing the silicon-containing layer, delivering the substrate into the processing region of the semiconductor processing chamber.

13. The semiconductor processing method of claim 11, further comprising:
increasing a pressure within the processing region of the semiconductor processing chamber while forming the plasma of the hydrogen-containing precursor.

14. The semiconductor processing method of claim 11, wherein the silicon-containing layer further comprises nitrogen, carbon, and/or a dopant, and wherein the hydrogen-containing precursor comprises diatomic hydrogen.

15. The semiconductor processing method of claim 11, wherein forming the plasma of the silicon-containing precursor is performed at a first plasma power, and wherein forming the plasma of the hydrogen-containing precursor is performed at a second plasma power greater than the first plasma power.

16. The semiconductor processing method of claim 11, wherein the semiconductor processing method is performed at a substrate temperature of greater than or about 200° C.

17. A semiconductor processing method comprising:
providing a silicon-containing precursor to a processing region of a semiconductor processing chamber;
depositing a silicon-containing layer within the processing region of the semiconductor processing chamber;
subsequent depositing the silicon-containing layer, providing a substrate to the processing region of the semiconductor processing chamber;
forming a plasma of a hydrogen-containing precursor within the processing region of the semiconductor processing chamber; and
depositing a silicon-containing material on the substrate disposed within the processing region of the semiconductor processing chamber.

18. The semiconductor processing method of claim 17, wherein the silicon-containing layer further comprises nitrogen, carbon, and/or a dopant, and wherein the hydrogen-containing precursor comprises diatomic hydrogen.

19. The semiconductor processing method of claim 17, wherein the silicon-containing layer is deposited by plasma-enhanced deposition performed at a first plasma power, and wherein forming the plasma of the hydrogen-containing precursor is performed at a second plasma power greater than the first plasma power.

20. The semiconductor processing method of claim 17, wherein the processing region of the semiconductor processing chamber is defined between a faceplate and a substrate support, wherein the silicon-containing layer is deposited on the faceplate, wherein the faceplate is maintained at a first temperature, and wherein the substrate support is maintained at a second temperature greater than the first temperature.
